(19) United States
(12) Patent Application Publication
(10) Pub. No.: US 2006/0145281 A1
(43) Pub. Date: Jul. 6, 2006

(54) Semiconductor device, liquid crystal device, electronic apparatus, and method of manufacturing semiconductor device

(75) Inventor: Hiroaki Jiroku, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/296,407

(22) Filed: Dec. 8, 2005

(30) Foreign Application Priority Data
Jan. 6, 2005 (JP) 2005-001796

(51) Int. Cl. H01L 31/0232; H01L 27/12; H01L 29/76

(52) U.S. Cl. 257/435; 257/66; 257/347

(57) ABSTRACT

A semiconductor device includes a substrate that is provided with a first main surface and a second main surface, a light shielding film that is disposed in a groove formed in the first main surface, and a semiconductor element that has a semiconductor film. The light shielding film is disposed between the second main surface and the semiconductor film.

### BACKGROUND

1. Technical Field

The present invention relates to a semiconductor device, to a liquid crystal device, to an electronic apparatus, and to a method of manufacturing the semiconductor device.

2. Related Art

There has been known a light valve for a video projector, an image sensor, and an active-matrix liquid crystal display device which use an active-matrix substrate, which is obtained by forming active elements such as thin film semiconductor devices for driving pixels on an insulating substrate made of quartz, glass, or the like.

Although projection light is incident on a thin film semiconductor device used in a light valve, if the projection light is directly or indirectly incident on a semiconductor film corresponding to a channel forming region of the thin film semiconductor device, photo leakage current is generated in the region due to a photoelectric effect, thereby deteriorating the characteristics of the thin film semiconductor device. Further, when light is incident onto an image pixel's periphery, there is a possibility that the light is reflected by metal wiring lines or the like and therefore the circuit pattern of the image pixel's periphery or the like is projected to be displayed.

In order to prevent the above-mentioned phenomenon, JP-A-11-194360 discloses a method of preventing light from being incident on a semiconductor film or regions at the vicinities of pixels by forming a light shielding film between a substrate and a semiconductor film.

However, if the light shielding film is formed on a substrate, a step difference between a surface of the substrate and a surface of the light shielding film is generated as shown in FIG. 6 of JP-A-11-194360. Therefore, when an insulating film and a semiconductor film are laminated thereon, a surface of the insulating film and a surface of the semiconductor film are not flat.

If a thin film semiconductor device is formed by using such a semiconductor film, an element having the step difference in a channel forming region and an element having a flat channel forming region are generated. A semiconductor element having the step difference in the channel forming region is different from a semiconductor element having a flat semiconductor film in the thickness of the semiconductor film, the thickness of the gate insulating film, an electric field effect, etc. Therefore, the electrical characteristics of the semiconductor element having the step difference in the channel forming region is different from those of the semiconductor element having the flat semiconductor film. For this reason, variations of the electrical characteristics occur among a plurality of semiconductor elements formed on the same substrate.

Further, if the semiconductor film is not formed in a flat manner, when the semiconductor film is melted by a thermal process, the material of the semiconductor film flows downward. Therefore, the thickness of the semiconductor film becomes inconsistent and a thinner part of the semiconductor film can be easily damaged.

### SUMMARY

An advantage of some aspects of the invention is that it provides a semiconductor device including a semiconductor element of which electrical characteristics are improved by forming a semiconductor film substantially flat.

In order to achieve the above-mentioned advantage, according to an aspect of the invention, a semiconductor device includes: a substrate that is provided with a first main surface and a second main surface; a light shielding film that is disposed in a groove formed in the first main surface; and a semiconductor element that has a semiconductor film. The light shielding film is disposed between the second main surface and the semiconductor film.

According to the above-mentioned construction, since the light shielding film is not laminated on the first main surface but is formed in the groove formed in the first main surface, it is possible to prevent a step difference from being generated between the first main surface and the surface of the light shielding film. Therefore, it is also possible to form the insulating film and the semiconductor film on the light shielding film such that the step difference is not generated, thereby improving the electrical characteristics of the semiconductor element.

In the semiconductor device according to the embodiment of the invention, preferably, an insulating film that is formed on the light shielding film is further included and the insulating film is in contact with a part of the first main surface. According to this construction, even though the insulating film formed on the light shielding film is in contact with the part of the first main surface, the light shielding film is disposed in the groove formed in the first main surface, so that it is possible to prevent the step difference from being generated in the insulating film.

Further, In the semiconductor device according to the embodiment of the invention, it is preferable that the light shielding film absorb or reflect at least a part of light incident on the second main surface. With this construction, even in a case of using the semiconductor device according to the embodiment of the invention as a light valve, it is possible to prevent light from being incident on a channel forming region of the semiconductor film. Therefore, it is possible to prevent photo leakage current from being generated due to a photoelectric effect.

Furthermore, in the semiconductor device according to the embodiment of the invention, it is preferable that a step difference be not generated between the part of the first main surface and an interface between the insulating film and the light shielding film. According to this construction, it is possible to planarize the insulating film formed over the light shielding film and the first main surface.

Furthermore, in the semiconductor device according to an aspect of the invention, it is preferable that the light shielding film be formed to cover the entire semiconductor film. According to this construction, it is possible to shield the entire semiconductor film from incident light or reflected light. Therefore, it is possible to prevent photo leakage current from being generated due to the photoelectric effect.

Depending on a material of the light shielding film or a method of manufacturing the light shielding film, there is a case in which cracks are easily generated in the light shielding film. In such a case, it is preferable that the light shielding film be formed to cover at least a channel forming region of the semiconductor film. With this construction, it is possible to prevent photo leakage current from being generated due to the photoelectric effect.

According to another aspect of the invention, a liquid crystal device and an electronic apparatus each includes the semiconductor device according to the above-described invention. They are high-performance electro-optical device and high-performance electronic apparatus, respectively, each having a semiconductor device with excellent properties obtained by forming a semiconductor film to be flat.

According to still another aspect of the invention, a method of manufacturing a semiconductor device includes: forming a groove in a first main surface of a substrate; forming a light shielding film in the groove; and forming a semiconductor element on the light shielding film.

According to the manufacturing method, since the light shielding film is not laminated on the first main surface but is formed in the groove formed in the first main surface, it is possible to prevent a step difference from being generated between the first main surface and the surface of the light shielding film. Therefore, it is also possible to prevent the step difference from being generated in the insulating film which covers the substrate and the light shielding film and in the semiconductor film formed on the insulating film.

Preferably, the method of manufacturing the semiconductor device according to the above aspect further includes forming an insulating film on the light shielding film, the insulating film being in contact with a part of the first main surface. At this time, it is preferable that a step difference is not generated between the part of the first main surface being in contact with the insulating film and an interface between the light shielding film and the insulating film.

The construction in which the step difference is not generated between the first main surface and the interface between the light shielding film and the insulating film can be realized by forming the light shielding film such that the step difference is not generated between the surface of the light shielding film and the first main surface.

Further, in the method, it is preferable that the forming of the light shielding film in the groove include forming a light shielding film on the groove and on the first main surface in the vicinity of the groove, and planarizing the light shielding film until the first main surface is exposed in the vicinity of the groove. According to this method, it is possible to form the top surface of the light shielding film and the first main surface to be even more flat.

Furthermore, in the method of manufacturing the semiconductor device according to the above aspect of the invention, it is preferable that the forming of the groove in the first main surface of the substrate include forming an etching mask that has an opening on a region of the first main surface where the groove is formed; and etching the substrate by using the etching mask, and the forming of the light shielding film in the groove include forming the light shielding film on the groove formed in the substrate and on the etching mask remaining on the substrate in the forming of the groove in the first main surface of the substrate; and removing the etching mask. According to the method, it is possible to easily remove a resist film and the light shielding film formed on the resist film, thereby being capable of forming the light shielding film only in the groove.

Furthermore, it is preferable that the first main surface and a surface of the light shielding film be planarized before forming the semiconductor element on the light shielding film. According to this method, it is possible to form the insulating film and the semiconductor film to be even more flat.

Furthermore, according to the method of the above aspect of the invention, the step difference is not generated in the insulating film and the semiconductor film. Therefore, even when a thermal process, that is, a process of melting and crystallizing the semiconductor film by irradiating a laser beam is performed, the material of the semiconductor film does not flow downward. As a result, it is possible to obtain, as the semiconductor film, a polycrystalline silicon film having a good crystallinity and little defects, which improves the electrical characteristics of the semiconductor element.

### BRIEF DESCRIPTION OF THE DRAWINGS

The invention will be described with reference to the accompanying drawings, wherein like numbers reference like elements.

FIG. 1 is a cross-sectional view illustrating a semiconductor device according to a first embodiment of the invention.

FIG. 2 is a cross-sectional view illustrating a semiconductor device according to a second embodiment of the invention.

FIGS. 3A to 3E are views illustrating a manufacturing method of a semiconductor device according to an embodiment of the invention.

FIGS. 4A to 4F are views illustrating another manufacturing of a semiconductor device according to the embodiment of the invention.

FIG. 5 is a connection view of a liquid crystal device according to the embodiment of the invention.

FIG. 6A is a view showing a mobile phone as an example of an electronic apparatus according to an embodiment of the invention.

FIG. 6B is a view showing a video camera as another example of the electronic apparatus according to the embodiment of the invention.

FIG. 6C is a view showing a portable personal computer as anther example of the electronic apparatus according to the embodiment of the invention.

FIG. 6D is a view showing a head-mounted display as another example of the electronic apparatus according to the embodiment of the invention.

FIG. 6E is a view showing a rear projector as an example of the electronic apparatus according to the embodiment of the invention.

FIG. 6F is a view showing a front projector as an example of the electronic apparatus according to the embodiment of the invention.

FIG. 7A is a view illustrating the related art.

FIG. 7B is a view illustrating the related art.

### DESCRIPTION OF EXEMPLARY EMBODIMENTS

Hereinafter, embodiments of the invention will be described with reference to the drawings.

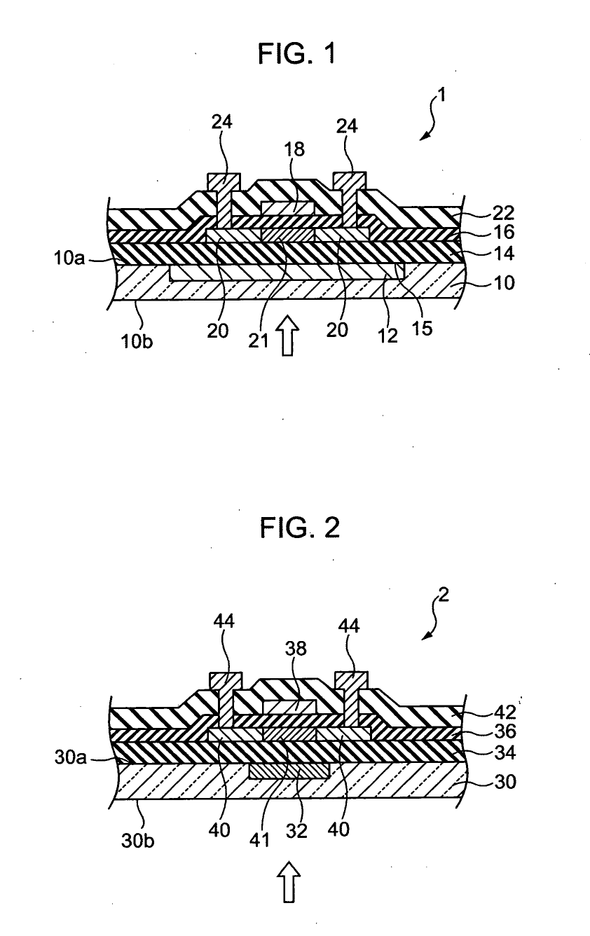

FIG. 1 is a cross-sectional view of a semiconductor element in a semiconductor device according to a first embodiment of the invention. In this embodiment, an active-matrix-type transmissive liquid crystal display device in which a thin film transistor (TFT) 1 is arranged as a semiconductor element on a substrate will be described as an example.

As shown in FIG. 1, the TFT 1 is formed on a substrate 10. The substrate 10 has a first main surface 10a and a second main surface 10b, and the first main surface 10a is provided with a groove. In the groove, a light shielding film 12 is formed between the second main surface 10b and the TFT 1. The light shielding film 12 absorbs or reflects light incident from the side of the second main surface 10b (in a direction shown by an arrow in FIG. 1), such that the light is prevented from irradiating a semiconductor film of the TFT 1.

As the substrate 10, a substrate made of, for example, quartz, glass, silicon, or the like can be used, but it is more preferable to use a quartz substrate having high transmittance. Further, the light shielding film 12 can be formed of, for example, a metal, such as Ti, Cr, W, Ta, Mo, Pd, or a metal alloy such as metal silicide.

In this embodiment, the TFT 1 is arranged on the substrate 10 with an insulating film 14 interposed therebetween, the insulating film 14 being formed so as to cover the first main surface 10a and the light shielding film 12. Between the first main surface 10a and an interface between the light shielding film 12 and the insulating film 14, there is hardly a step difference, and the insulating surface 14 is formed substantially flat.

The TFT 1 includes a semiconductor film composed of a source/drain region 20 and a channel forming region 21, an insulating film 16 composed of a silicon oxide film and the like staked on the semiconductor film, a gate electrode 18 formed on the insulating film 16, an insulating film 22 formed so as to cover the insulating film 16 and the gate electrode 18, and a source/drain electrode 24 formed in a contact hole passing through the insulating films 16 and 22.

In this embodiment, a surface of the light shielding film 12 is formed larger than the area of the semiconductor film of the TFT 1, such that light can be prevented from being incident on the entire semiconductor film.

FIG. 2 is a cross-sectional view of the semiconductor element in a semiconductor device according to a second embodiment of the invention. This embodiment is the same as the above-mentioned first embodiment, except that a light shielding film 32 is formed so as to have an area slightly larger than a channel forming region 41 of a semiconductor film of a TFT 2.

In this embodiment, although light is incident on a part of the semiconductor film, since it is possible to prevent the light from being incident on the channel forming region 41, it is possible to prevent photo leakage current from being generated due to a photoelectric effect. If the light shielding film has a large area, cracks are easily generated depending on the material thereof. Therefore, in this case, the above-mentioned construction is advantageous in which only the channel forming region 41 is shielded from light.

Next, a method of manufacturing a semiconductor device according to an embodiment of the invention will be described. Since substantially the same manufacturing method can be used in the first and second embodiments, the method will be described by using the same reference numerals as in the first embodiment, for convenience.

Formation of Groove and Light Shielding Film

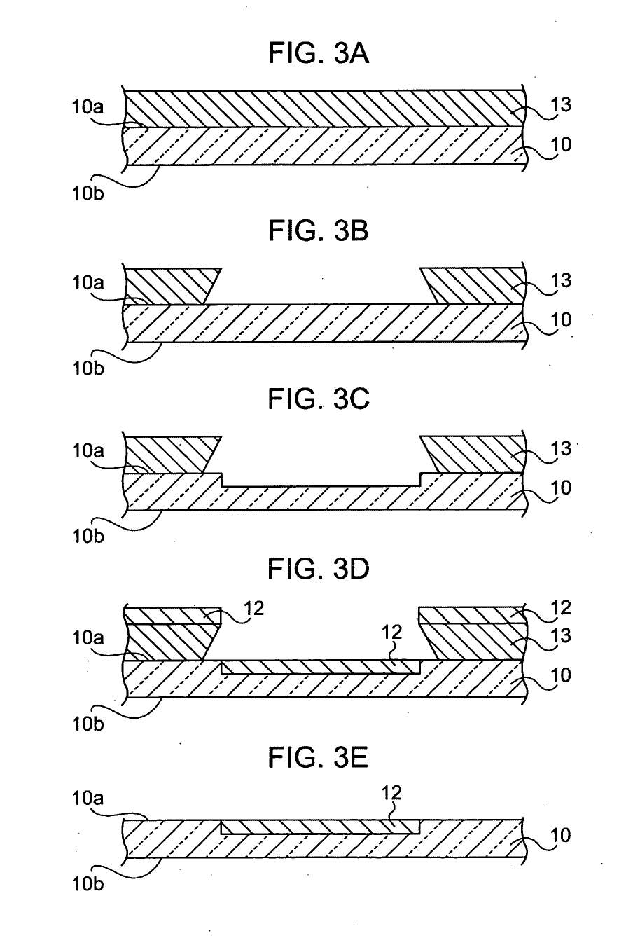

First, as shown in FIG. 3A, a photoresist film 13 is formed on a first main surface 10a of a substrate 10. The photoresist film 13 is formed in a larger area containing an area where a groove is formed. Subsequently, as shown in FIG. 3B, in the area where grooves are formed, the photoresist film 13 is removed so as to form an opening. The opening of the photoresist film 13 has preferably a reversely tapered shape in which the cross section of the opening on the side of the substrate 10 is smaller. Next, as shown in FIG. 3C, a groove is formed in the substrate 10 by an etching method. When the depth of the groove is set to the same level as that of the thickness with which a light shielding film is easily formed, it becomes easy to form the first main surface and the surface of the light shielding film flat with each other.

After forming the groove, as shown in FIG. 3D, a light shielding film 12 is formed on the groove and the photoresist film 13. As the light shielding film 12, for example, a metal film made of Ti, Cr, W, Ta, Mo, Pd, or the like, or a metal alloy film made of metal silicide or the like can be used. Subsequently, when the photoresist film 13 is peeled off, the light shielding film 12 formed on the photoresist film 13 can be removed together with the photoresist film. This is called a lift-off technology. As a result, as shown in FIG. 3E, only the light shield film 12, which is formed in the groove of the substrate, remains. If the photoresist after forming the opening has a reversely tapered shape, it is easy to apply the lift-off technology, since it is difficult to continuously form the light shielding film on the groove and the photoresist film 13.

The less the difference between the depth of the groove and the thickness of the light shielding film, the better. The difference is preferably less than 50 nm, more preferably, less than 10 nm, and most preferably, less than 1 nm. When the difference is less than 1 nm, the semiconductor film is formed to be substantially flat. However, since it is difficult to control the depth of the groove or the thickness of the light shielding film, the light shielding film is occasionally formed with a thickness having a larger level than the depth of the groove. In this case, when the photoresist film is removed, some step difference between the first main surface 10a and the light shielding film 12 is generated. At this time, if the step difference is eliminated by an etching method, a CMP (chemical mechanical polishing) method, or the like, it is possible to form an flat semiconductor film.

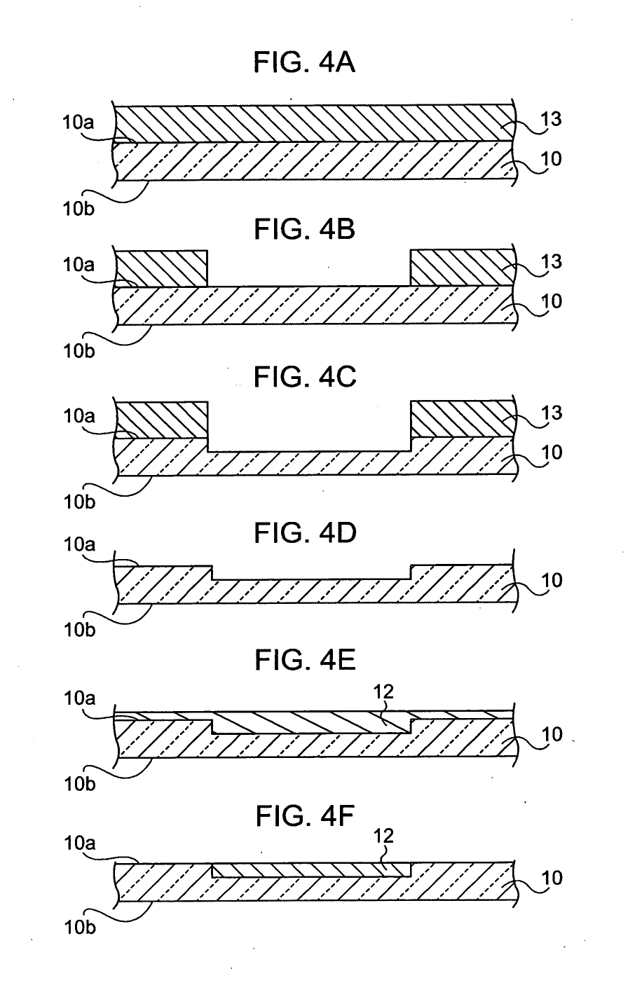

Further, the groove and the light shielding film can also be formed by a method, which will be described below with reference to FIGS. 4A to 4F.

First, as shown in FIGS. 4A to 4C, the first main surface 10a of the substrate 10 is formed by the same method as shown in FIGS. 3A to 3E. Then, as shown in FIG. 4D, the photoresist film 13 is removed.

Next, after forming the light shielding film 12 so as to cover overall the groove and the substrate 10, the light shielding film formed on portions other than the groove is removed by a planarizing method such as an etching method or a CMP method, such that the first main surface 10a of the substrate is exposed. In this way, as shown in FIG. 4F, the light shielding film 12 is formed to be buried in the substrate without any step difference between the light shielding film 12 and the first main surface 10a.

Formation of Semiconductor Element

Next, referring back to FIG. 1, a process of forming a semiconductor element will be described.

First, on the substrate 10 formed with the light shielding film buried therein, a silicon oxide film is formed as an insulating film 14. The silicon oxide film is formed with a thickness of several hundred nanometers (nm) by, for example, a PECVD (plasma enhanced chemical vapor deposition) method, an LPCVD (low pressure chemical vapor deposition) method, or a physical vapor deposition such as a sputtering method.

Subsequently, an amorphous silicon film is formed as a semiconductor film. Further, the amorphous silicon film can be crystallized such that the electric characteristics of the semiconductor element are improved. A crystallizing method may include, for example, a solid phase crystallization method or a melt crystallization method. The solid phase crystallization method is a method in which anneal is performed under an inert atmosphere at a temperature of 500° C. to 700° C. for several hours. In the solid phase crystallization method, the semiconductor film is crystallized in a solid state. However, a silicon film crystallized by the solid phase crystallization method has generally many defects. For this reason, in this invention, it is preferable to use a melt crystallization method.

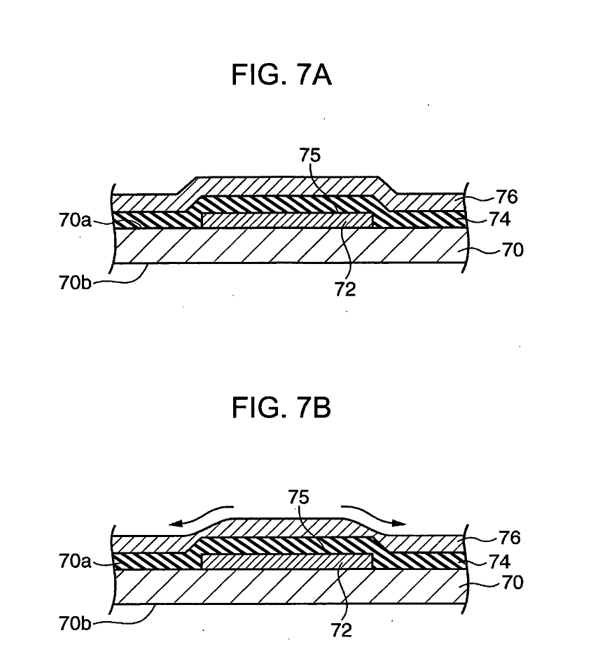

The melt crystallization method is a method in which a semiconductor film is melted and solidified so as to be crystallized. As a melt crystallization method, a laser anneal method is generally used in which a semiconductor film is irradiated by a laser beam so as to be melted. As described above, according to the method according to the related art in which a light shielding film is laminated on a substrate (see FIG. 7A), since a light shielding film 72 is formed on a first main surface 17a of a substrate 70, a step difference between the first main surface 70a and the interface 75 between the light shielding film 72 and an insulating film 74 is generated. In this state, when a laser beam irradiates a semiconductor film 76, the melted semiconductor film flows downward to be solidified. Therefore, the thickness of the semiconductor film becomes different depending on the location (see FIG. 7B). Further, in the general laser anneal method, a semiconductor film is repeatedly irradiated by laser beams. When a part of the semiconductor film becomes thinner due to a first irradiation, it causes a second irradiation to be performed onto the semiconductor film under a condition other than the optimal condition. For this reason, the semiconductor film can be damaged occasionally. Further, when the laser irradiation condition is optimized in advance for the thinner thickness, the thicker part is insufficiently crystallized.

In contrast, according to the method of the invention, since the insulating film 14 and the semiconductor film are formed to be substantially flat with each other, it is possible to obtain a homogeneous and high-performance semiconductor film without being damaged.

As a laser beam to be irradiated onto a semiconductor film, a pulse laser beam is preferable, and in particular, a KrF excimer laser beam having a wavelength of about 248 nm, a XeCl excimer laser beam having a wavelength of about 308 nm, a second harmonics of a ND:YAG laser beam having a wavelength of about 532 nm and a second harmonics of a Nd:YVO₄ laser beam, and a fourth harmonics of a ND:YAG laser beam having a wavelength of about 266 nm and a fourth harmonics of a Nd:YVO₄ laser beam may be irradiated, for example, with a pulse width of 30 nsec and an energy density of 0.4 to 1.5 J/cm². When these beams are irradiated onto a semiconductor film, the semiconductor film is melted, solidified, and crystallized.

After crystallizing the semiconductor film, patterning is performed to remove a part unnecessary for the formation of TFT. In this way, it is possible to obtain a semiconductor film formed into a necessary shape.

Next, on the insulating film 14 and the semiconductor film, a silicon oxide film 16 is formed. The silicon oxide film 16 can be formed by, for example, thermal oxidation or plasma oxidation of a silicon film. When these methods are used, it is possible to lower the interface state density between the semiconductor film and the silicon oxide film, while the semiconductor film becomes thinner or the silicon oxide film cannot be formed thick due to a low oxidation rate. Also, the silicon oxide film 16 can be formed by an electron cyclotron resonance PECVD method (ECR-CVD method) or a PECVD method. When the silicon oxide film is formed by a CVD method after performing thermal oxidation or plasma oxidation, it is possible to lower the interface state density between the semiconductor film and the silicon oxide film and to form the silicon oxide film into a desired thickness. The silicon oxide film 16 functions as a gate insulating film of a TFT. Since the semiconductor film is flat, the silicon oxide film 16, which is formed thereon as a gate insulating film, also is flat. Therefore, it is possible to form a gate insulating film regardless of the presence of the light shielding film.

Subsequently, on the silicon oxide film 16, a metallic film made of Ta or Al is formed by a sputtering method and then patterned so as to form a gate electrode 18. When the highest process temperature after forming the gate electrode is about 1000° C., a metallic film cannot be used as the gate electrode. In such a case, the gate electrode is composed of a polycrystalline silicon film into which impurity ions are implanted. Since the semiconductor film and the gate insulating film are flat, the gate electrode 18 formed thereon also is flat. Therefore, it is possible to form the gate electrode to be flat regardless of the presence of the light shielding film.

Next, the impurity ions to be donors or acceptors are implanted by using the gate electrode 18 as a mask such that a source/drain region 20 and a channel forming region 21 are self-aligned with regard to the gate electrode 18. In a case of manufacturing an NMOS transistor, for example, phosphorous elements serving as impurity elements are implanted into the source/drain region 30 in a concentration of 1×10¹⁶ cm⁻². Then, in order to activate the impurity elements, a thermal process is performed at a temperature of 250° C. to 1000° C. or a XeCl excimer laser beam irradiation is performed with an energy density of about 400 mJ/cm².

Next, on the silicon oxide film 16 and the gate electrode 18, a silicon oxide film 22 is formed. The silicon oxide film 22 can be formed to have a thickness of, for example, about 500 nm, by a PECVD method. Then, contact holes are opened through the silicon oxide films 16 and 22 to reach the source/drain region 20 and source/drain electrodes 24 are formed in the contact holes and on the vicinities of the contact holes on the silicon oxide film 22. The source/drain electrodes 24 may be formed, for example, by depositing Al by a sputtering method. Further, a contact hole is opened through the silicon oxide film 22 to reach the gate electrode and a terminal electrode (not shown) for the gate electrode 18 is formed. As described above, a TFT 1 is formed as a semiconductor element according to an embodiment of the invention.

Liquid Crystal Device

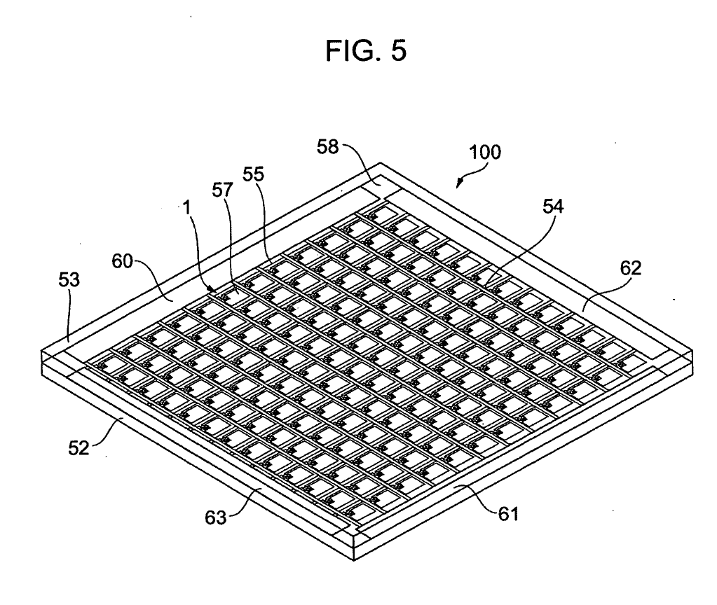

FIG. 5 shows a liquid crystal display device 100 as an example of a liquid crystal device according to an embodiment of the invention.

As shown in FIG. 5, the liquid crystal display device 100 includes an element substrate 52 having a TFT 1, a counter substrate 53 opposite to the element substrate 52, and a liquid crystal layer (not shown) made of liquid crystal having positive dielectric anisotropy between the element substrate (active-matrix substrate) 52 and the counter substrate 53.

The liquid crystal display device 100 has a display pixel region where a pixel circuit having a plurality of source lines (data lines) 54 and a plurality of gate lines (scanning lines) 55 intersected with each other is formed, and a driving circuit region where driving circuits are formed to supply driving signals to the source lines 54 and the gate lines 55, respectively.

In each of the intersections between the source lines 54 and the gate line 55 disposed on the inner surface side of the element substrate 52, a TFT 1 is formed to perform a switching operation on a corresponding pixel electrode 57 (load). In other words, in each of pixels arranged in a matrix, one TFT 1 and one pixel electrode 57 are provided. Further, on the entire inner surface of the counter substrate 53, one common electrode 58 is formed over the plurality of pixels arranged in a matrix.

Meanwhile, driving circuits (source drivers) 60 and 61 that control the drive of the pixels connected to the TFTs 1 are formed on the inner surface side of the element substrate 52 in the same manner as the TFTs 1, and have a plurality of TFTs (not shown). The driving circuits 60 and 61 are supplied with control signals from a control circuit (not shown) and generate driving signals (data signals) for driving the TFTs 1 on the basis of the control signals. Further, in the same manner as the driving circuits 60 and 61, driving circuits 62 and 63 that control the drive of the pixels connected to the TFTs 1 have a plurality of TFTs and generate driving signals (scanning signals) for driving the TFTs 1 on the basis of the control signals supplied thereto.

Electronic Apparatus

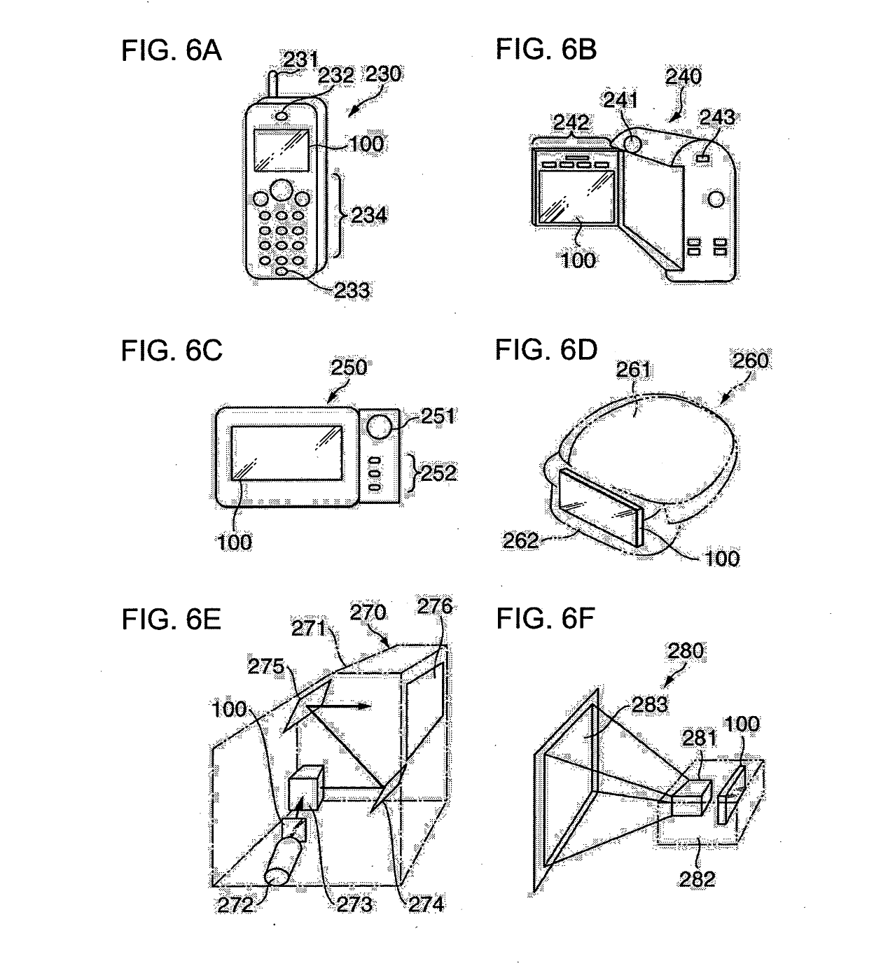

FIGS. 6A to 6F show examples of an electronic apparatus according to an embodiment of the invention. The electronic apparatus according to the embodiment of the invention includes an active-matrix substrate, which is a semiconductor device according to the embodiment of the invention obtained by forming TFTs in the above-mentioned manner.

FIG. 6A shows an example of a mobile phone provided with a semiconductor device manufactured by the manufacturing method of the invention. The mobile phone 230 has a liquid crystal display device (display panel) 100, an antenna 231, a voice output portion 232, a voice input portion 233, and an operation portion 234. The method of manufacturing the semiconductor device according to the embodiment of the invention may be applied to a method of manufacturing the display panel 100, a method of manufacturing a semiconductor device provided for a built-in integrated circuit, etc. FIG. 6B shows an example of a video camera, which has a semiconductor device manufactured by the manufacturing method of the invention. The video camera 240 has an electro-optical device (display panel) 100, an image receiver 241, an operation portion 242, and a voice input portion 242. The method of manufacturing the semiconductor device according to the embodiment of the invention may be applied to the method of manufacturing the display panel 100, the method of manufacturing the semiconductor device provided for a built-in integrated circuit, etc.

FIG. 6C shows an example of a portable personal computer provided with a semiconductor device manufactured by the manufacturing method of the invention. The computer 250 has an electro-optical device (display panel) 100, a camera unit 251, and an operation portion 252. The method of manufacturing the semiconductor device according to the embodiment of the invention may be applied to the method of manufacturing the display panel 100, the method of manufacturing a semiconductor device provided for a built-in integrated circuit, etc. FIG. 6D shows an example of a head-mounted display having a semiconductor device manufactured by the manufacturing method of the invention. The head-mounted display 260 has an electro-optical device (display panel) 100, head unit 261, and an optical recess 262. The method of manufacturing the semiconductor device according to the embodiment of the invention may be applied to the method of manufacturing the display panel 100, the method of manufacturing a semiconductor device provided for a built-in integrated circuit, etc.

FIG. 6E shows an example of a rear projector having a semiconductor device manufactured by the manufacturing method of the invention. The projector 270 has an electro-optical device (optical modulator) 100, a light source 272, an optical synthesizing system 273, mirrors 274 and 275 in a casing 271. The method of manufacturing the semiconductor device according to the embodiment of the invention may be applied to the method of manufacturing the optical modulator 100, the method of manufacturing a semiconductor element provided for a built-in integrated circuit, etc. FIG. 6F shows an example of a front projector having a semiconductor device manufactured by the manufacturing method of the invention. The projector 280 has an electro-optical device (image display source) 100 and an optical system 281 in a casing 282 and can display images on a screen 283. The method of manufacturing the semiconductor device according to the embodiment of the invention may be applied to the method of manufacturing the image display source 100, the manufacturing method of a semiconductor element provided for a built-in integrated circuit.

The method of manufacturing the semiconductor element according to the embodiment of the invention is not limited to the above-mentioned examples. The manufacturing method can be applied for manufacturing any other electronic apparatuses. In addition to the above-mentioned examples, for example, the manufacturing method can be applied to a fax machine having a display function, a finder of a digital camera, a portable TV, a DSP device, a PDA, an electronic organizer, an electronic billboard, a display for advertising, an IC card, etc.

Further, the invention is not limited to the above-mentioned embodiments but can be changed or modified in the scope of the invention. For example, in the above-mentioned embodiments, the semiconductor film is composed of a silicon film but it is not limited thereto. Furthermore, in the above-mentioned embodiments, as a semiconductor device, an active-matrix substrate is used which has a TFT, (semiconductor element) but the semiconductor device is not limited thereto. The semiconductor device may have other elements (for example, a thin film diode). Besides, in the above-mentioned embodiment, as the TFT, a top-gate TFT is used, but a bottom gate TFT can be used.

The entire disclosure of Japanese Patent Application No. 2005-001796, filed Jan. 6, 2005 is expressly incorporated by reference herein.

What is claimed is:

1. A semiconductor device comprising:
a substrate that is provided with a first main surface and a second main surface;
a light shielding film that is disposed in a groove formed in the first main surface; and
a semiconductor element that has a semiconductor film,
wherein the light shielding film is disposed between the second main surface and the semiconductor film.

2. The semiconductor device according to claim 1, further comprising:
an insulating film that is formed on the light shielding film,
wherein the insulating film is in contact with a part of the first main surface.

3. The semiconductor device according to claim 1,
wherein the light shielding film absorbs or reflects at least a part of light incident on the second main surface.

4. The semiconductor device according to claim 2,
wherein a step difference is not generated between the part of the first main surface and an interface between the insulating film and the light shielding film.

5. The semiconductor device according to claim 1,
wherein the light shielding film is formed so as to cover the entire semiconductor film.

6. The semiconductor device according to claim 1,
wherein the light shielding film is formed so as to cover at least a channel forming region of the semiconductor film.

7. A liquid crystal device comprising the semiconductor device according to claim 1.

8. An electronic apparatus comprising the semiconductor device according to claim 1.

9. A method of manufacturing a semiconductor device, comprising:
forming a groove in a first main surface of a substrate;
forming a light shielding film in the groove; and
forming a semiconductor element on the light shielding film.

10. The method according to claim 9, further comprising:
forming an insulating film on the light shielding film, the insulating film being in contact with a part of the first main surface,
wherein a step difference is not generated between the part of the first main surface and an interface between the light shielding film and the insulating film.

11. The method according to claim 9,
wherein, in the forming of the light shielding film in the groove, the light shielding film is formed such that a step difference is not generated between a surface of the light shielding film and the first main surface.

12. The manufacturing method of a semiconductor device according to claim 9,
wherein the forming of the light shielding film includes:
forming a light shielding film on the groove and on the first main surface in the vicinity of the groove; and
planarizing the light shielding film until the first main surface is exposed in the vicinity of the groove.

13. The method according to claim 9,
wherein the forming of the groove in the first main surface of the substrate includes:
forming an etching mask that has an opening on a region of the first main surface where the groove is formed; and
etching the substrate by using the etching mask, and
the forming of the light shielding film in the groove includes:
forming the light shielding film on the groove formed in the substrate and on the etching mask remaining on the substrate in the forming of the groove in the first main surface of the substrate; and
removing the etching mask.

14. The method according to claim 9, further comprising:
planarizing the first main surface and a surface of the light shielding film before forming the semiconductor element on the light shielding film.

15. The method according to claim 9,
wherein the forming of the semiconductor element on the light shielding film includes:
forming a semiconductor film on the substrate and the light shielding film, and
modifying the semiconductor film by a thermal process.

16. The method according to claim 15,
wherein, in the modifying of the semiconductor film, the semiconductor film is melted and crystallized by the thermal process.

17. The method according to claim 15,
wherein the thermal process is performed by irradiating a laser beam onto the semiconductor film.
